(19) United States
(12) Patent Application Publication
(10) Pub. No.: US 2006/0195750 A1
(43) Pub. Date: Aug. 31, 2006

(54) Simplifying Troubleshooting of Errors in Configurable Parameter Values Associated with Computer Supported Business-flows

(75) Inventors: Vishal S. Deshmukh, Hyderabad (IN); Venkanna Mittakanti, AndraPradesh (IN)

Correspondence Address: LAW FIRM OF NAREN THAPPETA, C/O LANDON IP, INC., 1700 DIAGONAL ROAD, SUITE 450, ALEXANDRIA, VA, 22314, US

(73) Assignee: ORACLE INTERNATIONAL CORPORATION, Redwood Shores, CA (US)

(21) Appl. No.: 10/907,648

(22) Filed: Apr. 10, 2005

(30) Foreign Application Priority Data
Feb. 25, 2005 (IN) 173/CHE/2005

(51) Int. Cl. H04L 1/00; H03M 13/00; G08C 25/00; G06F 11/00; G06F 11/30

(52) U.S. Cl. 714/746

(57) ABSTRACT

A troubleshooting tool for simplifying troubleshooting of errors in configurable parameter values associated with computer supported business-flows. The parameter values affecting the business-flows are stored in the tables of a database system in one embodiment. An administrator specifies the set of parameters which determine the specific row of the table that would be used by the business-flow, and the manner (e.g., as an SQL query) in which the specific row is determined. A user then invokes the tool, selects a specific business-flow (or parameter) to troubleshoot. The tool receives values for the set of parameters specified by the administrator and retrieves the specific data element representing the value of the parameter of interest (according to the SQL query). The retrieved data element can be compared with an expected value to troubleshoot the business-flow.

### BACKGROUND OF THE INVENTION

1. Field of the Invention

The present invention relates to troubleshooting tools used associated with computer programs, and more specifically to a method and apparatus for simplifying troubleshooting of errors in configurable parameter values associated with computer supported business-flows.

2. Related Art

Computer supported business-flows are often implemented in various business environments. For example, in a purchase transactions scenario, an agent may place an order using a computer system, and the program processing the order may automatically (without requiring further action by the agent or other users) request (e.g., by sending an email) further authorization of the manager of the agent before placing the order for a number of units exceeding a specified threshold.

Parameter values are often associated with the business-flows. For example, parameter values may indicate the manager corresponding to each agent. Parameter values thus refer to specific user configured values (used by the application) to make the specific scenarios of the flow work in a desired manner.

There are often situations in which applications implementing computer supported business-flows need to be troubleshooted. An example of such a situation is when the parameter values are wrongly configured/set. In the illustrative example of above, the manager of a specific agent may be wrongly set, and accordingly the business-flow may not work in the desired manner at least when the agent places an order exceeding the threshold number of units.

There is often substantial overhead in troubleshooting of such errors. Often, support staff is employed to help users troubleshoot such errors. It is generally desirable that the overhead of such troubleshooting be minimized. Accordingly, there is a general need in the industry for tools which facilitate troubleshooting of errors in configurable parameter values associated with computer supported business-flows.

### BRIEF DESCRIPTION OF THE DRAWINGS

The present invention will be described with reference to the accompanying drawings briefly described below.

FIG. 1 is a block diagram of an example environment in which a trouble-shooting tool using several aspects of the present invention is implemented.

FIGS. 2A, 2B, 2C together contain tables which are used to illustrate an example problem solved by various aspects of the present invention.

FIG. 3 is a flowchart illustrating the manner in which an administrator may configure a trouble shooting tool enabling users to later perform troubleshooting according to various aspects of the present invention.

FIG. 4 is a flow chart illustrating the manner in which an user may access a trouble-shooting tool to determine errors in a business-flow.

FIG. 5 contains a screen in the trouble-shooting tool, accessible to the administrator while configuring the various parameters associated with a business-flow.

FIG. 6 contains a screen in the trouble-shooting tool, accessed by an user to perform trouble-shooting of a business-flow.

FIG. 7 contains a screen illustrating values for a configurable parameters and its associated value retrieved from the tables in an embodiment.

FIG. 8 is a block diagram illustrating an example embodiment in which various aspects of the present invention are operative when software instructions are executed.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF THE PREFERRED EMBODIMENTS

1. Overview

A tool provided according to an aspect of the present invention operates in conjunction with a data storage, which stores various parameter values used by business-flows during operation. The tool enables a first user (typically an expert) to specify the manner in which the specific value of a parameter of interest can be retrieved from the data storage, with the specific value of the parameter of interest corresponding the values of a set of other parameters which determine the value of the parameter of interest.

A second user (generally someone troubleshooting) can then provide input values for the set of other parameters and the tool displays the corresponding value of the parameter of interest retrieved from the data storage. The value thus displayed can be used by the second user to troubleshoot errors in configurable parameter values associated with computer supported business-flows. It should be appreciated that the tool can be applied in relation to multiple business-flows, and multiple users in the position of the second user can use the tool.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well_known structures or operations are not shown in detail to avoid obscuring the features of the invention.

2. Example Environment

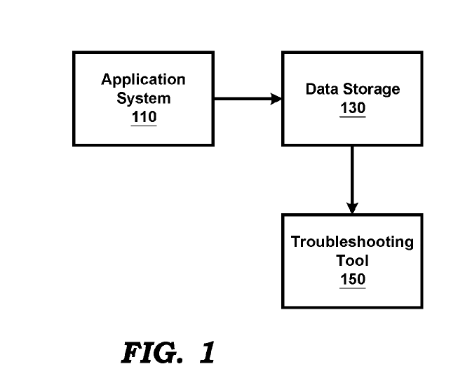

FIG. 1 is a block diagram illustrating an example environment in which various aspects of the present invention can be implemented. The environment is shown containing

application system 110, data storage 130 and troubleshooting tool 150. Each block is described below in further detail.

Application system 110 represents a system on which application supporting various business-flows are implemented. Application system 110 may be designed to retrieve parameter values (supporting or associated with the business-flows) from data storage 130. In an embodiment described below, data storage 130 corresponds to a database system which accepts read/write requests using structured queries. While not shown, the applications executing on application system 110 may be accessed by various client systems using networks such as Internet.

Troubleshooting tool 150 provided according to an aspect of the present invention simplifies troubleshooting of errors in configurable parameter values associated with computer supported business-flows, as described below in further detail. For illustration, an example problem that can be solved by troubleshooting tool 150 is first described.

3. Example Problem

An example problem encountered with ‘Purchase Order Approval’ supported by application system 110 is described below. As noted in the background section above, application system 110 needs to send an e_mail notification to a manager/supervisor, when application system 110 receives an order exceeding a pre-specified threshold.

For illustration, it is assumed that an agent ‘Pat Stock’ placed an order for 700 units (while the threshold set is 500 units), but her manager ‘Casey Brown’ did not receive approval email from application system 110.

It is further assumed that the reason for such non-receipt is the present data in data storage 130. Accordingly, first the data in data storage 130 is described, following the manner in which troubleshooting tool 150 enables resolution of the problem.

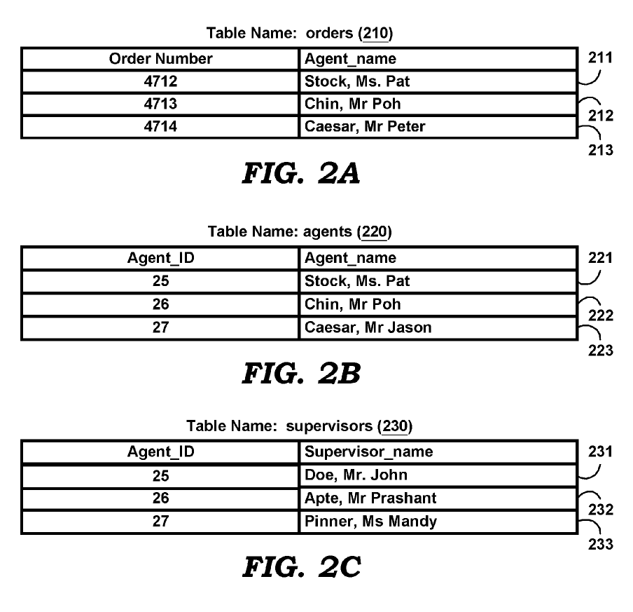

FIG. 2 is shown containing three tables—orders 210, agents 220 and supervisors 230. Orders 210 contains columns order-number and agent name. Thus, Ms. Pat Stock is shown placing order 4712 in row 211 shown in the table. Similarly, rows 212 and 213 indicate agent names of “Chin, Mr. Poh” and “Caesar, Mr. Peter” for order-numbers 4713 and 4714 respectively.

Agents table 220 contains columns agent-id and agent-name ‘Ms. Pat Stock’ is shown with an identifier of 25 in row 221. Rows 222 and 223 indicate agent-ids of 26 and 27 for agent-names “Chin, Mr Poh” and “Caesar, Mr Jason” respectively.

Supervisors table 230 is shown with columns agent-id and supervisor-name. Row 231 is shown indicating that the supervisor for agent-id of 25 is John Doe. Similarly, rows 232 and 233 indicate supervisors of “Apte, Mr. Prashant” and “Pinner, Ms. Mandy” for agent-id 26 and 27 respectively.

As can be readily appreciated, the supervisor name is expected to be Casey Brown, but data storage 130 indicates that the supervisor is John Doe. It is further assumed that data storage 130 contains the email-identifiers of each person in other tables (or other portions of the shown tables), and thus the emails were mis-directed to John Doe.

The manner in which troubleshooting tool 150 facilitates troubleshooting of such an error is described below in further detail.

4. Troubleshooting Tool

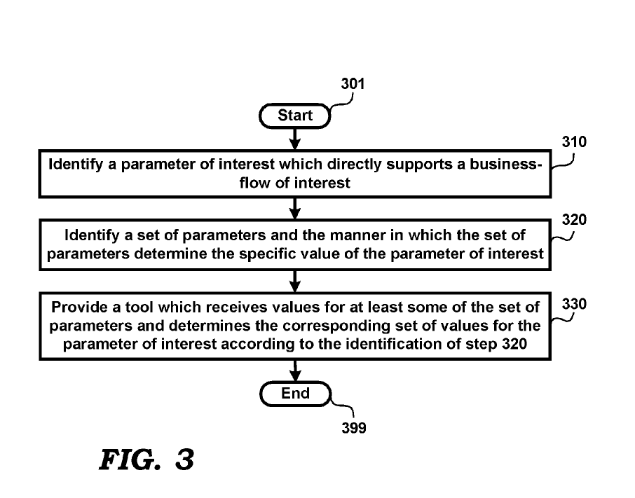

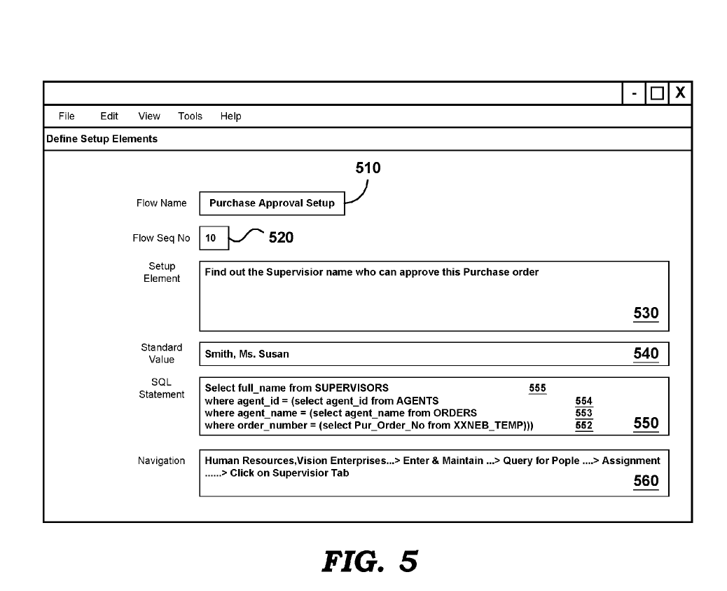

FIG. 3 is a flowchart illustrating the manner in which an administrator may setup a troubleshooting tool provided according to an aspect of the present invention, and FIG. 5 then illustrates the manner in which the tool can be used by a user for troubleshooting errors in configuration values. The steps of FIG. 3 are described with reference to the example environment of FIG. 1 for illustration. However, the flowchart can be implemented/used with other environments as well. The flowchart begins in step 301, in which control passes to step 320.

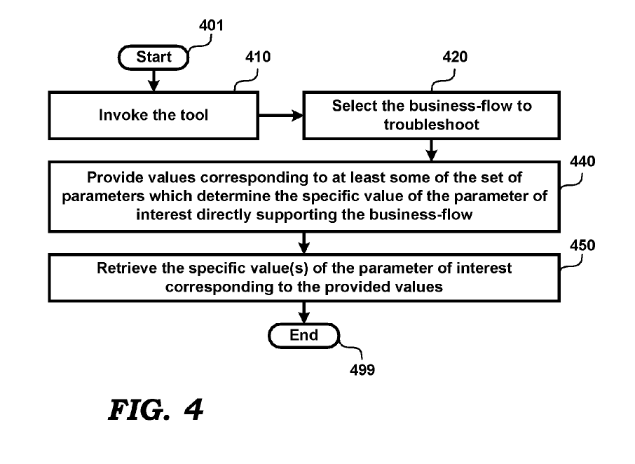

In step 310, the administrator identifies a parameter of interest which directly supports a business-flow of interest. In the example of FIG. 2, the parameter of interest is the Supervisor. In step 320, the administrator identifies a set of parameters and the manner in which the set of parameters determines the specific value of the parameter of interest. Assuming that the data is stored in a relational database, the relationships between various tables (or even different databases) needs to be examined for the determination/identification. Step 320 is illustrated in further detail with respect to FIG. 4 below.

In step 330, the administrator configures troubleshooting tool 150 to receives values for at least some of the set of parameters, and to determine the corresponding set of values for the parameter of interest according to the identification of step 320. Step 330 is also described in further detail with reference to FIG. 5. The flowchart of FIG. 3 ends in step 340.

It should be understood that troubleshooting tool 150 can be configured to troubleshoot errors in multiple computer supported business_flows. The manner in which troubleshooting tool 150 can then be used to troubleshoot the errors is described below with respect to FIG. 4.

FIG. 4 is a flowchart illustrating the manner in which a user may use a troubleshooting tool to troubleshoot errors according to various aspects of the present invention. The flowchart is described again with respect to FIG. 1 merely for illustration. The flowchart starts in step 401, in which control transfers to step 410.

In step 410, the user invokes the tool, either directly interfacing with the system or using a network (e.g., Internet), in a known way. In step 420, the user selects the specific business-flow sought to be troubleshoot. As noted above, troubleshooting tool 150 may be configured to troubleshoot several business-flows, and thus the specific business-flow of interest is selected.

In step 440, the user provides values corresponding to at least some of the set of parameters which determine the specific value of the parameter of interest directly supporting the business-flow. A suitable interface is provided to enable the user to input specific values.

In step 450, troubleshooting tool 150 retrieves the specific value(s) of the parameter of interest corresponding to the provided values. The retrieved value can be compared with the expected value to determine the source of the errors. The flowchart ends in step 499. The operation of FIGS. 3 and 4 is further illustrated with an example user interface below with respect to FIGS. 5-7.

5. Example User Interface

FIG. 5 contains a screen illustrating the manner in which troubleshooting tool 150 can be configured by an administrator (step 330) in one embodiment. Each portion of the screen is described briefly below.

The administrator can provide a user-friendly name associated with a present business-flow in portion 510. Thus, the user is shown to have entered ‘Purchase Approval Setup’. Flow sequence number 520 is a unique number generated by troubleshooting tool 150 for the present flow being configured. The description for the Business-flow is provided in portion 530. Portion 540 includes a default value for the parameter.

Portion 550 indicates the specific manner in which the corresponding value for the parameter of interest is retrieved. As seen there, a SQL query is provided assuming data storage 130 corresponds to a database system, assuming the table schema of FIG. 2. The query in portion 550 includes three sub-queries in lines 552, 553, 554 and 555.

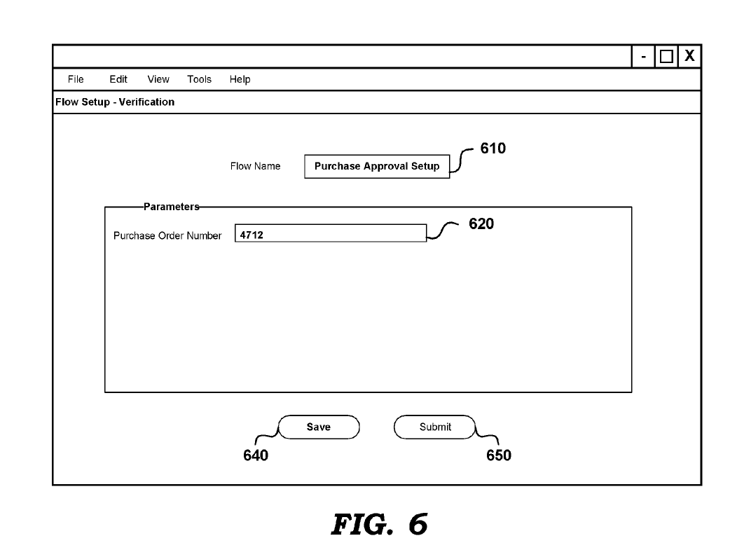

The select statement of line 552 operates to set purchase order number to specific purchase order number provided by the user for troubleshooting, assuming that the user-entered number (4712, from FIG. 2, as illustrated below with reference to FIG. 6) is stored in a table XXNEB_TEMP having a column pur_order_no.

The select statement of 553 operates to set agent-name to the name of the agent (Pat Stock, as shown above in FIG. 2) who created the Purchase Order by retrieving data from the corresponding row in table orders of 210.

The select statement of 554 operates to set agent_id for the agent_name (retrieved by the execution of sub-queries 552 and 553) to the value in a corresponding row in table agents (220). The sub-query of 555 operates to determine the supervisor name for the agent_id retrieved in line 553.

Portion 560 contains comments explaining the manner in which the correct parameter values can be set in the application (business-flow), if the user wishes to make the connection.

FIG. 6 contains a screen displayed when a user invokes the tool in one embodiment. In portion 610, the user selects the business-flow of interest. In portion 620, the user selects the purchase order number of interest. Portion 620 may represent a list-box, and the tool may provide the list of all purchase order identifiers stored in data storage 130. The user may then select the order number (4712) of interest.

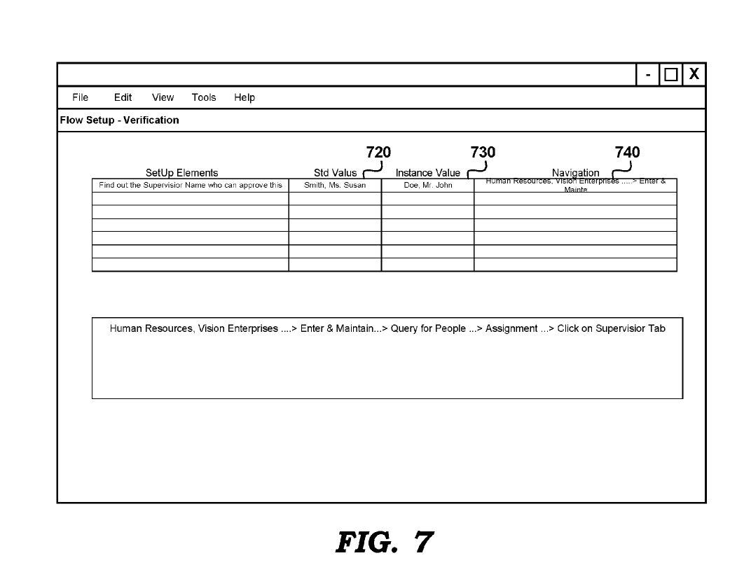

The user then selects ‘Save’ button, causing the entered value 4712 in a table entitled, XXNEB_TEMP. The troubleshooting tool 150 executes the command specified in portion 550 when the user selects the Submit button, and displays the retrieved value as shown in FIG. 7.

FIG. 7 contains a screen representing the display of the supervisor name (parameter of interest) to whom the emails are sent, for the data entered in FIG. 6. Consistent with the data stored in FIG. 2, John Doe is displayed as the retrieved parameter value in column 730. The default value provided by the administrator in field 540 is also shown displayed in column 720. The user may cause the value in the database (FIG. 2, supervisors table 230) to be changed (as instructed in a comment in navigation column 740) on noticing the difference.

It should be appreciated that the features described above can be implemented in various embodiments. The implementation of such features in troubleshooting tool 150 will be apparent to one skilled in the relevant arts by reading the disclosure provided herein. In general, modules may need to be provided to use pre-defined templates (forms) and enable an administrator to perform the configuration of step 220 (e.g., as in FIG. 5), then receive parameter values from a user and access data storage 130 to retrieve the parameter value of interest (as in FIGS. 3, 6 and 7) according to the information received from the administrator.

The description is continued with respect to an embodiment in which various features are operative when software instructions are executed.

6. Digital Processing System

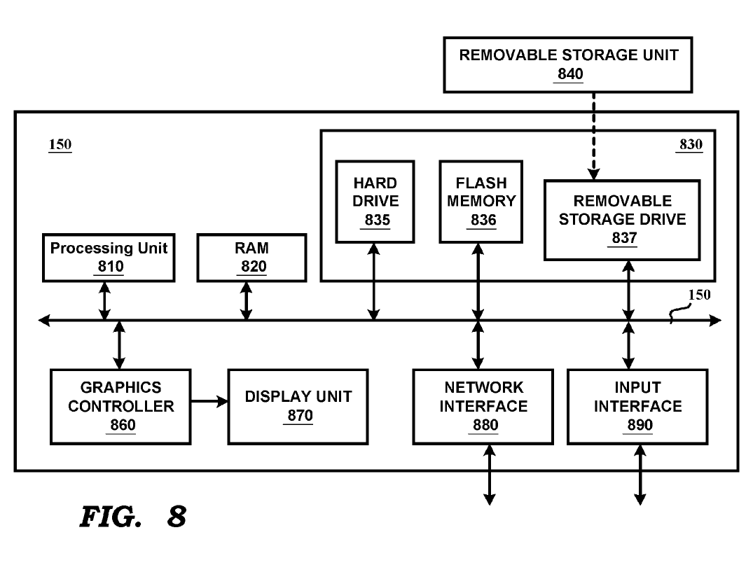

FIG. 8 is a block diagram illustrating the details of troubleshooting tool 150 in which various aspects of the present invention are operative by execution of appropriate software instructions. Troubleshooting tool 150 may contain one or more processors such as central processing unit (CPU) 810, random access memory (RAM) 820, secondary memory 830, graphics controller 860, display unit 870, network interface 880, and input interface 890. All the components except display unit 870 may communicate with each other over communication path 850, which may contain several buses as is well known in the relevant arts. The components of FIG. 8 are described below in further detail.

CPU 810 may execute instructions stored in RAM 820 to provide several features of the present invention. CPU 810 may contain multiple processing units, with each processing unit potentially being designed for a specific task. Alternatively, CPU 810 may contain only a single general purpose processing unit. RAM 820 may receive instructions from secondary memory 830 using communication path 850.

Graphics controller 860 generates display signals (e.g., in RGB format) to display unit 870 based on data/instructions received from CPU 810. Display unit 870 contains a display screen to display the images defined by the display signals. Input interface 890 may correspond to a key_board and/or mouse. Network interface 880 provides connectivity to a network (e.g., using Internet Protocol), and may be used to communicate with the other systems of FIG. 1.

Secondary memory 830 may contain hard drive 835, flash memory 836 and removable storage drive 837. Secondary memory 830 may store the data (templates/forms used in FIGS. 5-7, the business-flows configured by the administrator as in FIG. 5, temporary storage of table XXNEB_TEMP, etc.) and software instructions (e.g., to execute the logic of FIGS. 3 and 4), which enable troubleshooting tool 150 to provide several features in accordance with the present invention.

Some or all of the data and instructions may be provided on removable storage unit 840, and the data and instructions may be read and provided by removable storage drive 837 to CPU 810. Floppy drive, magnetic tape drive, CD_ROM drive, DVD Drive, Flash memory, removable memory chip (PCMCIA Card, EPROM) are examples of such removable storage drive 837.

Removable storage unit 840 may be implemented using medium and storage format

compatible with removable storage drive 837 such that removable storage drive 837 can read

the data and instructions. Thus, removable storage unit 840 includes a computer readable storage medium having stored therein computer software and/or data.

In this document, the term “computer program product” is used to generally refer to removable storage unit 840 or hard disk installed in hard drive 835. These computer program products are means for providing software to troubleshooting tool 150. CPU 810 may retrieve the software instructions, and execute the instructions to provide various features of the present invention described above.

7. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents. Also, the various aspects, features, components and/or embodiments of the present invention described above may be embodied singly or in any combination in a data storage system such as a database system.

What is claimed is:

1. A method of simplifying troubleshooting of errors in the value configured for a parameter, said parameter being associated with an application supporting a business_flow, said method being performed in a troubleshooting tool, a data storage containing said value of said parameter, said method comprising:
receiving a set of values for at least some of a set of parameters which determine the value for said parameter; and
retrieving from said data storage a data element according to a manner in which said set of values determine the value of said parameter,
wherein said data element is compared for equality with an expected value for said parameter to troubleshoot said errors in said application supporting said business-flow.

2. The method of claim 1, wherein said parameter comprises a column in a table, said table containing a plurality of rows, said set of values of said set of parameters determining a row which provides the value for said parameter, said method further comprising:
determining a specific row to be retrieved in said table based on said set of values for said set of parameters, wherein said data element is contained in said column of said specific row.

3. The method of claim 2, further comprising enabling an administrator to specify said manner and said set of parameters as being needed to troubleshoot said business-flow.

4. The method of claim 3, wherein said table is contained in a database and said manner comprises a structured query which retrieves said data element from said table in said database.

5. The method of claim 2, wherein said application stores said value in said data storage.

6. A system enabling an user to troubleshoot errors in the value configured for a parameter, said parameter being associated with an application supporting a business-flow, a data storage containing said value of said parameter, said system comprising:
means for receiving a set of values for at least some of a set of parameters which determine the value for said parameter; and
means for retrieving from said data storage a data element according to a manner in which said set of values determine the value of said parameter,
wherein said data element is compared for equality with an expected value for said parameter to troubleshoot said errors in said application supporting said business-flow.

7. The system of claim 6, wherein said parameter comprises a column in a table, said table containing a plurality of rows, said set of values of said set of parameters determining a row which provides the value for said parameter, said system further comprising:
means for determining a specific row to be retrieved in said table based on said set of values for said set of parameters, wherein said data element is contained in said column of said specific row.

8. The system of claim 7, further comprising means for enabling an administrator to specify said manner and said set of parameters as being needed to troubleshoot said business-flow.

9. The system of claim 8, wherein said table is contained in a database and said manner comprises a structured query which retrieves said data element from said table in said database.

10. The system of claim 7, wherein said application stores said value in said data storage.

11. A computer readable medium carrying one or more sequences of instructions enabling a system to simplify troubleshooting of errors in the value configured for a parameter, said parameter being associated with an application supporting a business_flow, a data storage containing said value of said parameter, wherein execution of said one or more sequences of instructions by one or more processors contained in said system causes said one or more processors to perform the actions of:
receiving a set of values for at least some of a set of parameters which determine the value for said parameter; and
retrieving from said data storage a data element according to a manner in which said set of values determine the value of said parameter,
wherein said data element is compared for equality with an expected value for said parameter to troubleshoot said errors in said application supporting said business_flow.

12. The computer readable medium of claim 11, wherein said parameter comprises a column in a table, said table containing a plurality of rows, said set of values of said set of parameters determining a row which provides the value for said parameter further comprising:
determining a specific row to be retrieved in said table based on said set of values for said set of parameters, wherein said data element is contained in said column of said specific row.

13. The computer readable medium of claim 12, further comprising enabling an administrator to specify said manner and said set of parameters as being needed to troubleshoot said business_flow.

14. The computer readable medium of claim 1 3, wherein said table is contained in a database and said manner comprises a structured query which retrieves said data element from said table in said database.

15. The computer readable medium of claim 12, wherein said application stores said value in said data storage.
